(19) United States
(12) Patent Application Publication
(10) Pub. No.: US 2013/0343032 A1
(43) Pub. Date: Dec. 26, 2013

(54) POLARIZATION STRUCTURES, METHODS OF MANUFACTURING POLARIZATION STRUCTURE AND DISPLAY DEVICES INCLUDING POLARIZATION STRUCTURES

(71) Applicant: SAMSUNG DISPLAY CO., LTD., Yongin-City (KR)

(72) Inventors: Jong-Soo Lee, Yongin-City (KR); Seung-Yo Yang, Yongin-City (KR); Sang-Min Yi, Yongin-City (KR)

(73) Assignee: SAMSUNG DISPLAY CO., LTD., Yongin-City (KR)

(21) Appl. No.: 13/765,108

(22) Filed: Feb. 12, 2013

(30) Foreign Application Priority Data
Jun. 20, 2012 (KR) 10-2012-0066168

(51) Int. Cl. G02B 5/30; F21V 9/14

(52) U.S. Cl. CPC G02B 5/3083; F21V 9/14; H01L 21/67
USPC 362/19; 359/489.07; 427/163.1

(57) ABSTRACT

A polarization structure may include at least one adhesion layer, a phase retarder layer disposed over the adhesion layer, a polarization layer disposed over the phase retarder layer, and a light blocking member disposed over a peripheral portion of the polarization layer, under the peripheral portion of the polarization layer or under a peripheral portion of the phase retarder layer. When a display device includes the polarization structure having the light blocking member, the display device may display an image with improved visibility and uniformity in an entire display area although the display device has a minimized bezel or does not have any bezel.

### CROSS REFERENCE TO RELATED APPLICATION

This application claims priority under 35 U.S.C. §119 to Korean patent Application No. 10-2012-0066168 filed on Jun. 20, 2012, the disclosure of which is hereby incorporated by reference herein in its entirety.

### BACKGROUND

1. Technical Field

The present disclosure relates to polarization structures, method of manufacturing polarization structures and display devices including polarization structures.

2. Discussion of the Related Technology

Display devices such as organic light emitting display (OLED) devices or liquid crystal display (LCD) devices may generally include a front cover covering a peripheral portion of a display panel on which an image is displayed. Further, a rear cover may be disposed on a back side of the display panel such that the front cover may be combined with the rear cover. The display panel module of the display device may be fastened to one of the front cover and the rear cover to be fixed between the front and the rear cover. The front and the rear covers may be mainly composed of metal or plastic.

A boss part may be usually disposed onto the front cover or the rear cover to provide sufficient binding force between the display panel module and the covers as the size of the display device is increased. When the display panel module is fastened to the front cover or the rear cover using the boss part, the size of the bezel covering the peripheral portion of the display panel may be increased. That is, the portion of the display panel on which the image is displayed may be partially covered by the bezel having the increased size, so that the effective display area of the display device may be reduced. This problem may have a bad influence on the increase of the size of the display device and also may cause the increase of the weight of the display device. Further, the display device may have a relatively complicated configuration because of the boss part and the related members for combining the display panel with the covers, and thus the cost for fabricating the display device may be increased.

Meanwhile, as described in Korean Patent Publication No. 2009-0122138, light may be penetrated into the peripheral portion of the display panel at which reflective members are not disposed after a polarization layer is attached to the entire region of the display panel. The image may be burred at the peripheral portion of the display panel because of the transmission of incident light, and thus the uniformity and visibility of the image may be deteriorated in the entire area of the display panel. To improve the uniformity of the image, a bezel having a relatively large width is disposed to cover the peripheral portion of the display panel where reflective elements such as metal wirings, driving circuits and controllers are not located. However, the display device may not ensure a large size and a light weight according as the bezel has increased dimensions.

Recently, an organic light emitting display device has been developed as a big size display device having a minimized bezel. However, metal wirings and driving circuits partially exist or do not exist at the peripheral portion of the display panel (e.g., the dead panel portion), so that the image may not be uniform on the entire display area of the display panel, and also the visibility of the image may be deteriorated at the peripheral portion of the display panel. Further, the display device may have a poor appearance because of the transmission of incident light at the peripheral portion of the display panel after attaching the polarization layer on the display panel.

### SUMMARY

Embodiments provide a polarization structure including a light blocking member to reduce a size of a bezel or to remove a bezel while improving a visibility and a uniformity of an image on a display panel.

Embodiments provide a method of manufacturing a polarization structure including a light blocking member to reduce a size of a bezel or to remove a bezel while improving a visibility and a uniformity of an image on a display panel.

Embodiments provide a display device improving a visibility and uniformity of an image by a polarization structure including a light blocking member to reduce a size of a bezel or to remove a bezel.

One aspect provides a polarization structure including a first adhesion layer; a phase retarder layer disposed over the first adhesion layer; a polarization layer disposed over the phase retarder layer and a light blocking member disposed over a peripheral portion of the polarization layer.

In embodiments, the light blocking member may have a substantial frame shape or a substantial ring shape. The light blocking member may include metal, alloy, metal compound, black material, insulation resin, light blocking paint, etc. For example, the light blocking member may include cobalt carbide (CoCx), iron oxide (FeOx), terbium (Tb)-based compound, diamond-like carbon, titanium black, chrome (Cr), molybdenum (Mo), chrome oxide (CrOx), molybdenum oxide (MoOx), phenylene black, aniline black, cyanine black, nigrosine acid black, black resin, ink containing polyethyleneterephthalate (PET)-based resin, ink containing urethane resin, etc.

In embodiments, a protection layer may be additionally disposed over the polarization layer. Here, the light blocking member may be disposed over a peripheral portion of the protection layer. In some embodiments, a low reflective layer may be additionally disposed over the protection layer and the light blocking member.

In some embodiments, a second adhesion layer may be disposed over the polarization layer. Here, the light blocking member may be disposed on a peripheral portion of the second adhesion layer. Further, a protection layer may be disposed over the light blocking member and the second adhesion layer, and a low reflective layer may be disposed over the protection layer.

In some embodiments, a first protection layer may be disposed over the phase retarder layer and the polarization layer, and a second protection layer may be disposed over the light blocking member and the second adhesion layer. Additionally, a low reflective layer may be disposed over the second adhesion layer.

Another aspect provides a polarization structure including an adhesion layer, a light blocking member disposed over a peripheral portion of the adhesion layer, a phase retarder layer disposed over the light blocking member and the adhesion layer, a polarization layer disposed over the phase retarder layer, a protection layer disposed over the polarization layer, and a low reflective layer disposed over the protection layer.

Still another aspect provides a polarization structure including a first adhesion layer, a phase retarder layer disposed over the first adhesion layer, a second adhesion layer disposed over the phase retarder layer, a light blocking member disposed over a peripheral portion of the second adhesion layer, a polarization layer disposed over the light blocking member and the second adhesion layer, a protection layer disposed over the polarization layer, and a low reflective layer disposed over the protection layer.

Yet another aspect provides a method of manufacturing a polarization structure. In the method, after providing a base film, a first adhesion layer may be formed over the base film. A phase retarder layer may be formed over the first adhesion layer. A polarization layer may be formed over the phase retarder layer. A light blocking member may be formed over a peripheral portion of the polarization layer. A low reflective layer may be formed over the light blocking member and the polarization layer.

In the formation of the light blocking member according to embodiments, a light blocking layer may be formed over the polarization layer. After a mask may be formed over the light blocking layer, the light blocking layer may be patterned using the mask.

In the formation of the light blocking member according to embodiments, a preliminary light blocking member may be formed over the peripheral portion of the polarization layer. The preliminary light blocking member may be thermally treated.

In embodiments, the light blocking member may be formed with an adhesive including black dye.

In embodiments, a protection layer may be additionally formed over the polarization layer. Here, the light blocking member may be disposed on a peripheral portion of the protection layer.

In some embodiments, a second adhesion layer may be additionally formed over the polarization layer. Here, the light blocking member may be disposed on a peripheral portion of the second adhesion layer. A protection layer may be additionally formed over the light blocking member and the second adhesion layer.

In some embodiments, a first protection layer may be additionally formed between the phase retarder layer and the polarization layer. A second protection layer may be additionally formed between the light blocking member and the second adhesion layer.

A further aspect provides a method of manufacturing a polarization structure. In the method, a base film may be provided. An adhesion layer may be formed over the base film. A light blocking member may be formed over a peripheral portion of the adhesion layer. A phase retarder layer may be formed over the light blocking member and the adhesion layer. A polarization layer may be formed over the phase retarder layer. A protection layer may be formed over the polarization layer. A low reflective layer may be formed over the protection layer.

One aspect provides a method of manufacturing a polarization structure. In the method, after providing a base film, a first adhesion layer may be formed over the base film. A phase retarder layer may be formed over the first adhesion layer. A second adhesion layer may be formed over the phase retarder layer. A light blocking member may be formed over a peripheral portion of the second adhesion layer. A polarization layer may be formed over the light blocking member and the second adhesion layer. A protection layer may be formed over the polarization layer. A low reflective layer may be formed over the protection layer.

One aspect provides a display device including a polarization structure. The display device may include a first substrate having a switching device, a first electrode electrically connected to the switching device, a pixel defining layer being disposed over the first electrode and having an opening exposing the first electrode, a light emitting structure disposed over the exposed first electrode, a second electrode disposed over the light emitting structure, a second substrate disposed over the second electrode, and a polarization structure disposed over the second substrate. The polarization structure may include a light blocking member disposed at a peripheral portion.

According to embodiments, the polarization structure may include the light blocking member disposed over or under the peripheral portion of the polarization layer, or under the peripheral portion of the phase retarder layer. The penetration of incident light may be prevented at the peripheral portion of the display panel by the light blocking member, so that the appearance of the display panel may be improved and also the uniformity and the visibility of the image may be enhanced in the entire display area of the display device.

### BRIEF DESCRIPTION OF THE DRAWINGS

Embodiments can be understood in more detail from the following description taken in conjunction with the accompanying drawings, in which:

FIGS. 1 to 3 are cross-sectional views illustrating a method of manufacturing a polarization structure in accordance with embodiments.

FIGS. 4 to 6 are cross-sectional views illustrating a method of manufacturing a polarization structure in accordance with some embodiments.

FIGS. 7 and 8 are cross-sectional views illustrating a method of manufacturing a polarization structure in accordance with embodiments.

FIGS. 9 and 10 are cross-sectional views illustrating a method of manufacturing a polarization structure in accordance with embodiments.

FIGS. 11 and 12 are cross-sectional views illustrating a method of manufacturing a polarization structure in accordance with embodiments.

FIG. 13 is a cross-sectional view illustrating a display device having a polarization structure in accordance with embodiments.

### DESCRIPTION OF EMBODIMENTS

The embodiments are described more fully hereinafter with reference to the accompanying drawings. The invention may, however, be embodied in many different forms and should not be construed as limited to the embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. Like or similar reference numerals refer to like or similar elements throughout. As used herein, the term “and/or” includes any and all combinations of one or more of the associated listed items.

It will be understood that, although the terms first, second, third etc. may be used herein to describe various elements, components, regions, layers, patterns and/or sections, these elements, components, regions, layers, patterns and/or sections should not be limited by these terms. These terms are only used to distinguish one element, component, region, layer pattern or section from another region, layer, pattern or section. Thus, a first element, component, region, layer or section discussed below could be termed a second element, component, region, layer or section without departing from the teachings of embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “under” other elements or features would then be oriented “over” the other elements or features. Thus, the exemplary term “below” can encompass both an orientation of over and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross sectional illustrations that are schematic illustrations of illustratively idealized embodiments (and intermediate structures) of the invention. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

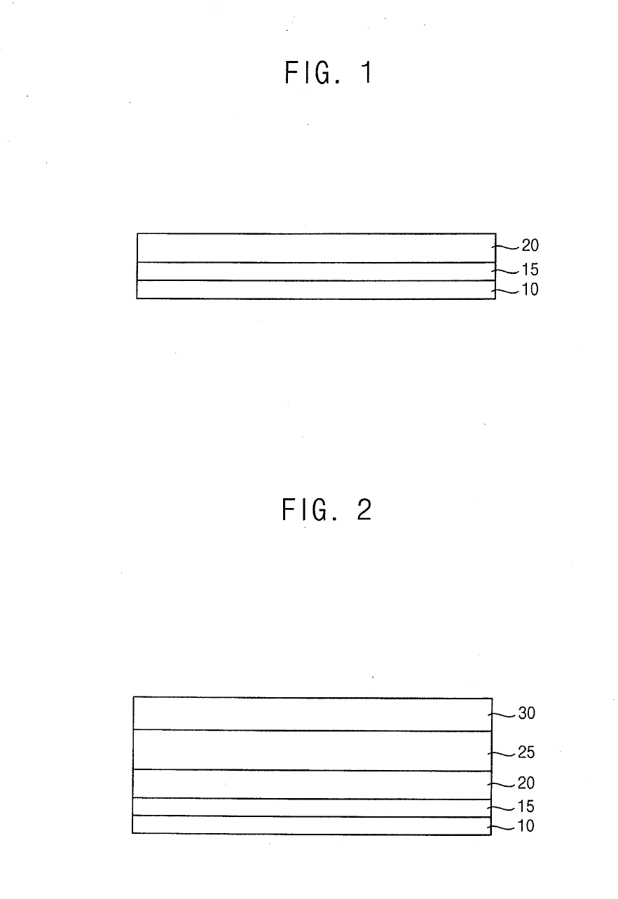

FIGS. 1 to 3 are cross-sectional views illustrating a method for manufacturing a polarization structure in accordance with embodiments.

Referring to FIG. 1, an adhesion layer 15 may be formed on a base film 10. The base film 10 may protect the adhesion layer 15 formed thereon. The adhesion layer 15 may be easily detached from the base film 10 because of the characteristics of the base film 10. For example, the base film 10 may include release paper (i.e., separate paper) coated with silicon resin, fluoroplastics, etc. The base film 10 may be removed from the adhesion layer 15 when the polarization structure is attached to a display panel of a display device such as a liquid crystal display (LCD) device, an organic light emitting display (OLED) device, an electrophoresis display device, etc. Thus, the polarization structure may be directly attached to the display panel of the display device. For example, the base film may have a thickness in a range of about 5 μm to about 20 μm.

The adhesion layer 15 may combine the polarization structure with the display panel of the display device. For example, the adhesion layer 15 may include a rubber-based adhesive, an acryl-based adhesive, a vinyl ether-based adhesive, a silicon-based adhesive, a urethane-based adhesive, etc. The adhesive layer 15 may have a thickness of about 5 μm to about 20 μm measured from an upper face of the base film 10. When the adhesion layer 15 includes a pressure-sensitive adhesive such as an acryl-based polymer adhesive or a vinyl ether-based polymer adhesive, an adhesion strength between the polarization structure and the display panel may be enhanced due to the adhesion layer 15 as a pressure is applied to the polarization structure and/or the display panel.

A phase retarder layer 20 may be formed on the adhesion layer 15. The phase retarder layer 20 may include a birefrigent film containing polymer, a liquid crystal alignment film, an orientation layer of liquid crystal polymer formed on a predetermined base material, etc. Examples of the polymer in the birefrigent film may include polycarbonate, polyvinylalcohol, polystyrene, polymethylmethacrylate, polypropylene, polyolefine, polyarylate, ployamide, polyethyleneterephthalate, triacetylcelluose, etc. The phase retarder layer 20 may include a uniaxial film or a biaxial film.

In embodiments, the phase retarder layer 20 may be directly formed on the adhesion layer 15, so that a thickness of the phase retardation layer 20 may be reduced. For example, the phase retardation layer 20 may have a thickness in a range of about 5 μm to about 50 μm based on an upper face of the adhesion layer 15. The phase retarder layer 20 may include a λ/4 retardation film or wave plate. The λ/4 retardation film may cause a phase retarder of λ/4 relative to two orthogonal polarized components of incident light, such that the λ/4 retardation film may convert a linearly polarized component into a circularly polarized component or may change a circularly polarized component into a linearly polarized component. For example, the phase retarder layer 20 may convert circular polarization light incident from the display panel of the display device into linear polarization light, or may convert linear polarization light into circularly polarization light. In some embodiments, the phase retarder layer 20 may include a λ/4 retardation film and a λ/2 retardation film in accordance with the configuration of the display device having the polarization structure.

Referring to FIG. 2, a polarization layer or polarizer layer 25 may be formed on the phase retarder layer 20. The polarization layer 25 may pass a polarized component of incident light along a predetermined polarization direction. For example, the polarization layer 25 may include an iodine-based material, a material containing dye, a polyen-based material, etc. In addition, the polarization layer 25 may have a relatively large thickness of about 10 μm to about 50 μm measured from an upper face of the phase retarder layer 20.

In embodiments, the polarization layer 25 may have an absorbtion axis and a polarization axis. The absorbtion axis of the polarization layer 25 may substantially correspond to the drawing orientation axis of dichromatic dyes or chains of iodine ions. Here, the polarized component of incident light oscillating along the absorbtion axis may become extinct by interaction with electrons included in the polarization layer 25. Meanwhile, the polarization axis may be substantially perpendicular to the absorbtion axis, and thus the polarized component of incident light oscillating along the polarization axis may pass through the polarization layer 25.

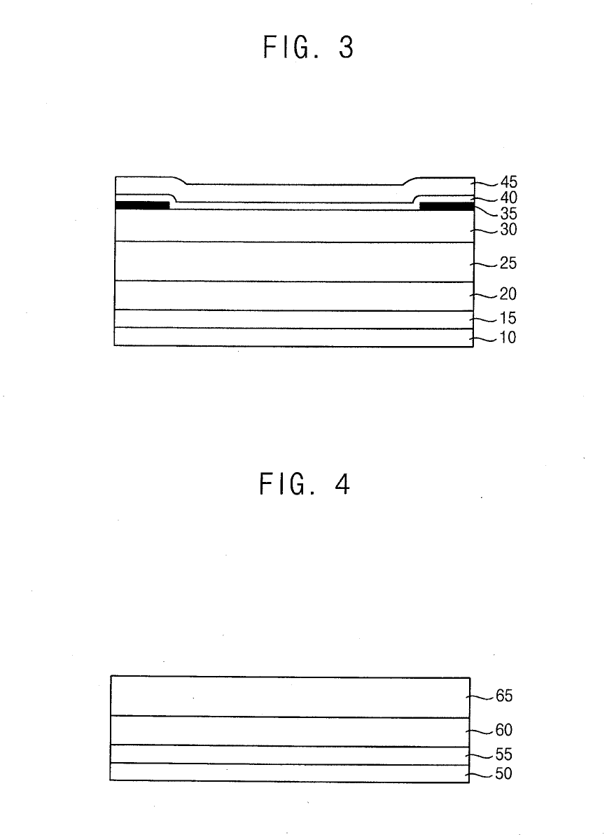

A protection layer 30 may be formed on the polarization layer 25. The protection layer 30 may protect the polarization layer 25 and also may serve as a base film for a light blocking member 35 (see FIG. 3) formed thereon. The protection layer 30 includes an optically isotropic film, so that the protection layer 30 may not have any substantial affect on the polarization characteristics of incident light. For example, the protection layer 30 may include triacetylcellulose (TAC), cycloolefin polymer, cycloolefin copolymer, polyethyleneterephthalate (PET), polypropylene, polycarbonate, polysulfone, polymethyl methacrylate, etc.

In embodiments, the protection layer 30 may have a relatively small thickness below 20 μm based on an upper face of the polarization layer 25. In some embodiments, the protection layer 30 may have a relatively large thickness in a range of about 20 μm to about 50 μm in accordance with the configuration of the display device.

Referring to FIG. 3, the light blocking member 35 may be formed on the protection layer 30. In embodiments, the light blocking member 35 may have a substantial polygon frame shape or a substantial polygon ring shape. For example, the light blocking member 35 may have a relatively small thickness of about 3 μm to about 10 μm measured from an upper face of the protection layer 30.

The light blocking member 35 may be disposed on a peripheral portion of the protection layer 30 or a border of the protection layer 30 (i.e., a peripheral portion or a border of the polarization structure). Thus, the light blocking member 35 may substantially cover the border or the peripheral portion of the display panel (e.g., an edge portion of the display panel) substantially corresponding to the border or the peripheral portion of the polarization structure when the polarization structure is combined with the display panel. For example, the light blocking member 35 may have a substantially polygonal ring shape such as a substantially rectangular ring shape in accordance with the shape of the display panel. However, the shape of the light blocking member 35 may vary in accordance with the shape of the display panel and/or the shape of the polarization structure. In this case, the light blocking member 35 may have a width varying according to the size of the display panel, the dimensions of wirings positioned at the peripheral portion of the display panel. That is, the width of the light blocking member 35 may be increased or decreased according to the configuration of the display device.

In embodiments, the light blocking member 35 may block the penetration of light incident into the peripheral portion of the display panel from an out side. Thus, the light blocking member 35 may reduce the width of the bezel to improve the entire visibility of image displayed on the display panel. Further, when the display device may not include a bezel, the image may be uniformly displayed in the entire display area of the display panel because of the light blocking member 35. Therefore, the uniformity and the visibility of the image at the peripheral portion of the display may be improved.

In embodiments, the light blocking member 35 may be formed using a metal compound, a black material, metal having a relatively low reflectivity, insulation resin, light blocking paint, etc. For example, the light blocking member 35 may include cobalt carbide (CoCx), iron oxide (FeOx), terbium (Te)-based compound, carbon (C), diamond-like carbon, titanium black, chrome (Cr), molybdenum (Mo), chrome oxide (CrOx), molybdenum oxide (MoOx), phenylene black, aniline black, cyanine black, nigrosine acid black, black resin, ink containing polyethyleneterephthalate-based resin, resin containing urethane resin, etc. These may be used alone or in a combination thereof. In addition, the light blocking member 35 may be formed on the protection layer 30 by a printing process, a spin coating process, a spray process, a chemical vapor deposition process, etc.

In the formation of the light blocking member 35 according to embodiments, a light blocking layer (not illustrated) may be formed on the protection layer 30, and then a mask (not illustrated) may be formed on the light blocking layer. Here, the mask may include a photoresist pattern or another etching mask containing a silicon compound. Using the mask as an etching mask, the light blocking layer may be patterned to form the light blocking member 35 on the protection layer 30. In this case, the light blocking member 35 may have a predetermined shape according to the shape of the display panel.

In the formation of the light blocking member 35 according to some embodiments, a preliminary light blocking member (not illustrated) may be formed on the peripheral portion of the protection layer 30, and then the preliminary light blocking member may be thermally treated to provide the light blocking member 35 on the protection layer 30. In this case, according to the shape of the display panel, the light blocking member 35 may have various shapes such as substantially polygonal ring shape, a substantially circular ring shape, a substantially elliptical ring shape, etc.

In the formation of the light blocking member 35 according to other embodiments, the light blocking member 35 may be formed on the protection layer 30 using an adhesive containing a black dye. For example, the light blocking member 35 having a predetermined shape may be attached to the peripheral portion of the protection layer 30 by interposing the adhesive therebetweeen. In this case, the light blocking member 35 may prevent the penetration of light at the peripheral portion of the display panel as well as the light blocking member 35 may attach the protection layer 30 to a low reflective layer 40 successively formed. The adhesive for the light blocking member 35 may include an adhesive resin, for example, acryl-based resin, urethane-based resin, polyisobutylene-based resin, styrene-butadiene rubber-based resin, rubber-based resin, polyvinylether-based resin, epoxy-based resin, melamine-based resin, polyester-based resin, phenol-based resin, silicon-based resin, etc. These may be used alone or in a combination thereof. In addition, examples of the black dye may include carbon black, chrome oxide, molybdenum oxide, iron oxide, titanium black, phenylene black, aniline black, cyanine black, nigrosine acid black, black resin, etc. These may be used alone or in a combination thereof.

Referring now to FIG. 3, the low reflective layer 40 may be formed on the protection layer 30 to cover the light blocking member 35. The low reflective layer 40 may be formed using silicon nitride (SiNx), silicon oxide (SiOx), a metal compound, etc. For example, the low reflective layer 40 may have a relatively small thickness of about 0.1 μm to about 5.0 μm based on an upper face of the protection layer 30.

In embodiments, the low reflective layer 40 may have a surface containing micro concave and convex structures to reduce the reflectivity of incident light. In some embodiments, the low reflective layer 40 may additionally include a hard coating film, a sticking prevention film, an anti-glare film, etc.

When the low reflective layer 40 includes the hard coating film, the low reflective layer 40 may have good hardness and sliding characteristics using ultraviolet-curable polymer such as silicon-based resin, so that the low reflective layer 40 may minimize damages or scratches to the surface of the polarization structure. In case that the low reflective layer 40 includes the sticking preventing film, a protection sheet 45 may be easily separated from the low reflective layer 40 because the tight adhesion between the low reflective layer 40 and the protection sheet 45 may be prevented. When the low reflective layer 40 includes the anti-glare film, the low reflective layer 40 may have the surface including the micro concave and convex structures by a roughening process such as a sand blast process or an embossing process, or a transparent fine particles mixing process. Thus, the low reflective layer 40 may prevent the reflection of external light to thereby improve the visibility of the image on the display panel. Example of the transparent fine particles may include silica, alumina, titania, zirconia, indium oxide (InOx), cadmium oxide (CdOx), conductive inorganic particles, organic particles containing transparent polymer particles, etc.

As illustrated in FIG. 3, the protection sheet 45 may be formed on the low reflective layer 40. The polarization structure includes the base film 10, the adhesion layer 15, the phase retarder layer 20, the polarization layer 25, the protection layer 30, the light blocking member 35, the low reflective layer 40 and the protection sheet 45. The protection sheet 45 may have a relatively large thickness of about 5 μm about 20 μm measured from an upper face of the low reflective layer 40. For example, the protection sheet 45 may include polyester-based resin, polyolefine-based resin, polypropylene-based resin, etc. The protection sheet 45 may protect the low reflective layer 40 and the light blocking member 35. The protection sheet 45 may be removed from the low reflective layer 40 after combining the polarization structure with the display panel. That is, the base film 10 and the protection sheet 45 may be removed from the polarization structure after the combination of the polarization structure and the display panel.

In a display device, incident light may penetrate into a peripheral portion of a display panel even though a polarization layer may be attached to a display panel. Hence, an image may be blurred at the peripheral portion of the display panel, and also an appearance of the display device may not be fine. Particularly, those problems may be serious to the current organic light emitting display device having a big size which may require an elegant appearance and may enlarge a display area thereof by reducing a size of a bezel or removing a bezel. The polarization structure according to embodiments may include the light blocking member 35 disposed over the polarization layer 25, and the light blocking member 35 may block penetration of incident light at the peripheral portion of the display panel. Therefore, the display device including the polarization structure may ensure improved appearance and also the image may have enhanced uniformity and visibility in the entire display area of the display device.

FIGS. 4 to 6 are cross-sectional views illustrating a method of manufacturing a polarization structure in accordance with some embodiments. In FIGS. 4 to 6, the detailed description about elements and element-forming-processes which are substantially the same with the elements and the processes described with reference to FIGS. 1 to 3 will be omitted for brevity.

Referring to FIG. 4, a first adhesion layer 55 may be formed on a base film 50. The base film 50 may include release paper coated with silicon resin, fluoroplastics, etc. When the polarization structure is attached to a display panel of a display device, the base film 50 may be removed from the first adhesion layer 55, and then the first adhesion layer 55 of the polarization structure may be attached to an upper face of the display panel. For example, the first adhesion layer 55 may include a rubber-based adhesive, an acryl-based adhesive, a vinyl ether-based adhesive, a silicon-based adhesive, a urethane-based adhesive, etc. The first adhesive layer 15 may have a relatively small thickness.

A phase retarder layer 60 may be formed on the first adhesion layer 55. The phase retarder layer 60 may have a thickness relatively larger than that of the base film 50 and/or that of the first adhesion layer 55. For example, a thickness ratio between the phase retarder layer 60 and the base film 50 or the first adhesion layer 55 may be in a range of about 1.0:0.1 to about 1.0:1.0. The phase retarder layer 60 may include a birefrigent film containing polymer, a liquid crystal alignment film, an orientation layer of liquid crystal polymer formed on a predetermined base material, etc. In embodiments, the phase retarder layer 60 may include a λ/4 retardation film and/or a λ/2 retardation film, and may convert circular polarization light incident from the display panel into linear polarization light, or may convert linear polarization light into circularly polarization light.

In some embodiments, the phase retarder layer 60 may have a relatively small thickness when the phase retarder layer 60 is directly coated on the first adhesion layer 55. For example, the phase retarder layer 60 may have a thickness substantially the same as or substantially similar to that of the first adhesion layer 55, or the thickness of the phase retarder layer 60 may be substantially smaller than that of the first adhesion layer 55.

Referring now to FIG. 4, a polarization layer 65 may be formed on the phase retarder layer 60. The polarization layer 65 may include an iodine-based material, material containing dye, a polyen-based material, etc. The polarization layer 65 may pass a predetermined polarized component of incident light, and may have a relatively large thickness from an upper face of the phase retarder layer 60. For example, a thickness ratio between the polarization layer 65 and the base film 50 or the first adhesion layer 55 may be in a range of about 1.0:0.1 to about 2.5:1.0.

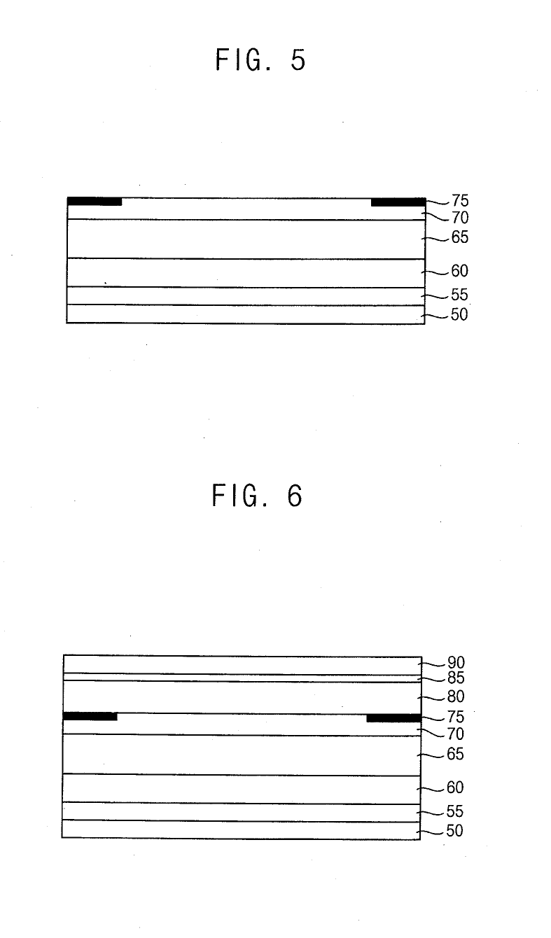

Referring to FIG. 5, a second adhesion layer 70 may be formed on the polarization layer 65. Here, the second adhesion layer 70 may include a material substantially the same as or substantially similar to that included in the adhesion layer 15 described with reference to FIG. 1. For example, the second adhesion layer 70 may include a material substantially the same as or substantially similar to that of the first adhesion layer 55. Alternatively, the first and the second adhesion layers 55 and 70 may be formed using different materials included in the adhesion layer 15, respectively.

A light blocking member 75 may be formed on a peripheral portion of the second adhesion layer 70 (i.e., a border or an edge portion of the second adhesion layer 70). In embodiments, the light blocking member 75 may be disposed on the second adhesion layer 70 to enhance an adhesion strength between the light blocking member 75 and the second adhesion layer 70 and an adhesion strength between the second adhesion layer 70 and a protection layer 80 (see FIG. 6). Therefore, the light blocking member 75 may be stably positioned at a desired position of the second adhesion layer 70.

The light blocking member 75 on the peripheral portion of the second adhesion layer 70 (i.e., a peripheral portion of the polarization structure) may have a substantially polygonal frame shape, a substantially polygonal ring shape, etc. The light blocking member 75 may have dimensions substantially varying in accordance with dimensions of the display panel and/or dimensions of wirings or circuits positioned at the peripheral portion of the display panel. The light blocking member 75 may include a material substantially the same as or substantially similar to that of the light blocking member 35 described with reference to FIG. 3. Additionally, the light blocking member 75 may be obtained by processes substantially the same as or substantially similar to those described with reference to FIG. 3. With the light blocking member 75, penetration of light may be blocked at the peripheral portion of the display panel and appearance of the display device may be enhanced. Further, visibility and uniformity of an image may be improved in the whole display area of the display panel.

In embodiments, the light blocking member 75 may be partially or fully buried in the peripheral portion of the second adhesion layer 70. For example, the protection layer 80 may be formed on the light blocking member 75 and the second adhesion layer 70, and then the protection layer 80 may be pressed to partially or completely bury the light blocking member 75 in the peripheral portion of the second adhesion layer 70. In this case, the light blocking member 75 may have improved positional stability because the protection layer 80 may be attached to the second adhesion layer 70.

Referring to FIG. 6, the protection layer 80 and a low reflective layer 85 may be formed on the light blocking member 75 and the second adhesion layer 70. The protection layer 80 and the low reflective layer 85 may include materials substantially the same as or substantially similar to those of the protection layer 30 and the low reflective layer 40 described with reference to FIG. 3, respectively.

A protection sheet 90 may be attached to the low reflective layer 85 to thereby manufacture the polarization structure including the base film 50, the first adhesion layer 55, the phase retarder layer 60, the polarization layer 65, the second adhesion layer 70, the light blocking member 75, the protection layer 80, the low reflective layer 85 and the protection sheet 90. The protection sheet 90 may have relatively small thickness. After the polarization structure is combined with the display panel, the protection sheet 90 may be removed from the low reflective layer 85.

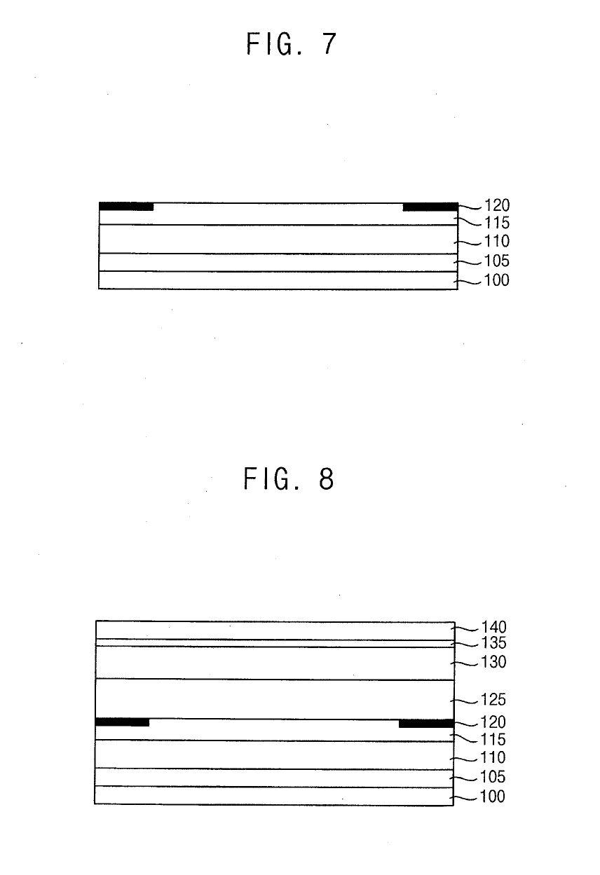

FIGS. 7 and 8 are cross-sectional views illustrating a method of manufacturing a polarization structure in accordance with some embodiments. In FIGS. 7 and 8, the detailed description about elements and element-forming-processes which are substantially the same with the elements and the processes described with reference to FIGS. 1 to 3 will be omitted for brevity.

Referring to FIG. 7, a first adhesion layer 105 may be formed on a base film 100. A phase retarder layer 110 may be formed on the first adhesion layer 105. The phase retarder layer 110 may include a λ/4 retardation film and/or a λ/2 retardation film in accordance with types of display devices.

A second adhesion layer 115 may be formed on the phase retarder layer 110, and a light blocking member 120 may be formed on a peripheral portion of the second adhesion layer 115 (e.g., a border or an edge portion of the second adhesion layer 115). In case that the light blocking member 120 is located on the second adhesion layer 115, the light blocking member 120 may have enhanced positional stability because the polarization layer 125 (see FIG. 8) may be combined with the second adhesion layer 115 by interposing the light blocking member 120 therebetween. In other words, the light blocking member 120 may be exactly placed at a desired position of the polarization structure. For example, the light blocking member 120 may have a substantially polygonal ring shape or a substantially polygonal frame shape on the peripheral portion of the second adhesion layer 115 (e.g., a peripheral portion of the polarization structure). A material included in the light blocking member 120 may be substantially the same as or substantially similar to the material in the light blocking member 35 described with reference to FIG. 3. When the display device includes the polarization structure having the light blocking member 120, the display device may have elegant appearance and may display a uniform image in the whole display area of the display panel by blocking penetration of light at the peripheral portion thereof.

In embodiments, the light blocking member 120 may be partially or wholly buried in the peripheral portion of the second adhesion layer 115. Such a light blocking member 120 may be obtained by the process substantially the same as or substantially similar to the process described with reference to FIG. 5.

Referring to FIG. 8, a polarization layer 125 may be formed on the second adhesion layer 115 and the light blocking member 120. The polarization layer 125 may pass a predetermined polarization component of incident light, and may have a relatively large thickness based on an upper face of the second adhesion layer 115.

A protection layer 130 and a low reflective layer 135 may be formed on the polarization layer 125. The protection layer 130 and the low reflective layer 135 may be formed using materials substantially the same as or substantially similar to those for the protection layer 30 and the low reflective layer 135 described with reference to FIG. 3, respectively.

A protection sheet 140 may be formed on the low reflective layer 135, and thus the polarization structure may be obtained. The protection sheet 140 may have a relatively small thickness. The protection sheet 140 may be removed from the polarization structure before or after combining the polarization structure with the display panel.

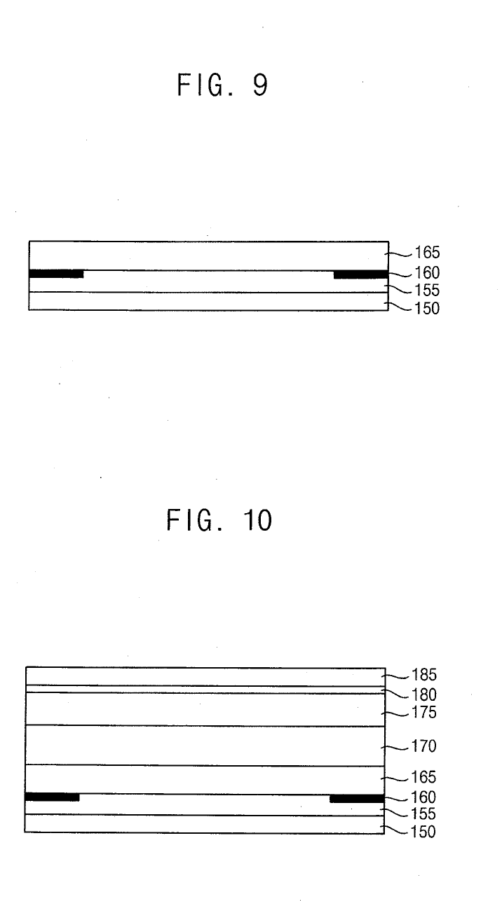

FIGS. 9 and 10 are cross-sectional views illustrating a method of manufacturing a polarization structure in accordance with some embodiments. In FIGS. 9 and 10, the detailed description about elements and element-forming-processes which are substantially the same with the elements and the processes described with reference to FIGS. 1 to 3 will be omitted for brevity.

Referring to FIG. 9, an adhesion layer 155 may be formed on the base film 150. For example, the base film 150 may include separate paper containing resin, and the adhesion layer 155 may include a pressure-sensitive adhesive.

A light blocking member 160 may be formed on a peripheral portion of the adhesion layer 155. In this case, the light blocking member 160 may be entirely or partially buried in the adhesion layer 155. For example, upper faces of the light blocking member 160 and the adhesion layer 155 may be placed on the same plane. The light blocking member 160 may be formed using a metal compound, insulation resin, black material, metal having a relatively low reflectivity, light blocking paint, etc. The light blocking member 160 may be obtained by a process substantially the same as or substantially similar to the process described with reference to FIG. 3 or FIG. 5.

A phase retarder layer 165 may be formed on the light blocking member 160 and the adhesion layer 155. The phase retarder layer 165 may be directly disposed on the adhesion layer 155 having the light blocking member 160 thereof, such that a thickness of the phase retarder layer 165 may be decreased. This phase retarder layer 165 may be obtained by a process substantially the same as or substantially similar to the process describe with reference to FIG. 2.

Referring to FIG. 10, a polarization layer 170 and a protection layer 175 may be formed on the phase retarder layer 165. A specific polarized component of incident may pass through the polarization layer 170, and an underlying structure including the light blocking member 160 may be protected by the protection layer 175.

A low reflective layer 180 and a protection sheet 185 may be formed on the protection layer 175, thereby manufacturing the polarization structure. The low reflective layer 180 may be formed using a silicon compound and/or a metal compound. The protection sheet 185 may be removed from the low reflective layer 180 after or before attaching the polarization structure to a display panel.

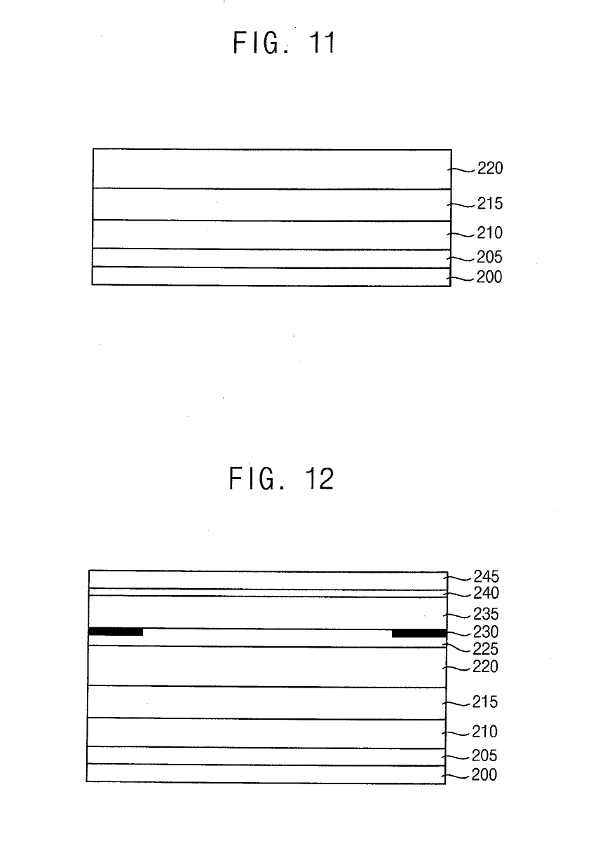

FIGS. 11 and 12 are cross-sectional views illustrating a method of manufacturing a polarization structure in accordance with some embodiments. In FIGS. 11 and 12, the detailed description about elements and element-forming-processes substantially the same with the elements and the processes described with reference to FIGS. 1 to 3 will be omitted for brevity.

Referring to FIG. 11, a first adhesion layer 205 and a phase retarder layer 210 may be formed on a base film 200. For example, the first adhesion layer 205 may include a pressure-sensitive adhesive and the phase retarder layer 210 may include a birefrigent film containing polymer, a liquid crystal alignment film, an orientation layer of liquid crystal polymer formed on a predetermined base material, etc. In embodiments, the phase retarder layer 210 may include a λ/4 retardation film and/or a λ/2 retardation film.

A first protection layer 215 and a polarization layer 220 may be formed on the phase retarder layer 210. The first protection layer 215 may include acetate-based resin without limiting thereto. In embodiments, the first protection layer 215 may include triacetylcellulose having a saponification surface using alkali to improve durability of the first protection layer 215. The polarization layer 220 may include an iodine-based material, material containing dye, a polyen-based material, etc.

Referring to FIG. 12, a second adhesion layer 225 may be formed on the polarization 220, and a light blocking member 230 may be formed on a peripheral portion of the second adhesion layer 225. The light blocking member 230 may be fully or partially buried in the peripheral portion of the second adhesion layer 225, so that the light blocking member 230 may be precisely disposed at a desired position of the polarization structure (i.e., a desired position of the display device). When the polarization structure having the light blocking member 230 is employed in the display device, the display device may ensure an image with improved uniformity and visibility even though the display device does not have any bezel on the display panel thereof.

A second protection layer 235 may be formed on the light blocking member 230 and the second adhesion layer 230. The second protection layer 235 may include a material substantially the same as or substantially similar to that of the first protection layer 215. Alternatively, the first and the second protection layers 215 and 235 may include different materials, respectively.

A low reflective layer 240 and a protection sheet 245 may be formed on the second protection layer 235. The low reflective layer 240 may be formed using a silicon compound or a metal compound. The protection sheet 245 may be formed using transparent resin or translucent resin. The low reflective layer 40 and the protection sheet 245 are formed, and the manufacture of the polarization structure may be completed.

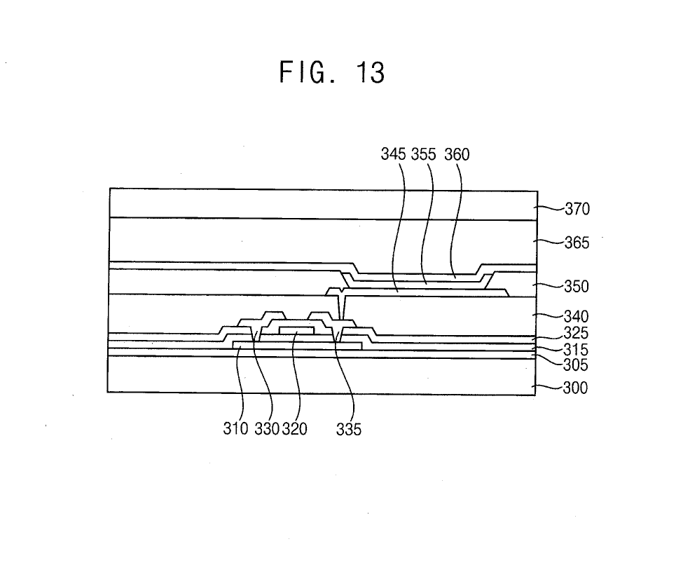

FIG. 13 is a cross-sectional view illustrating a display device including a polarization structure in accordance with embodiments. The display device illustrated in FIG. 13 may include a polarization structure 370 having a configuration substantially the same as or substantially similar to that of the polarization structure described with reference to FIG. 3, FIG. 6, FIG. 8, FIG. 10 or FIG. 12. Additionally, an organic light emitting display device is illustrated in FIG. 13 as the display device, however, the polarization structure 370 may be employed in other display devices such as a liquid crystal display device, an electrophoresis display device, etc.

Referring to FIG. 13, the display device may include a first substrate 300, a switching device, a first electrode 345, a light emitting structure 365, a second electrode 360, a second substrate 365, the polarization 377, etc.

A buffer layer 305 may be disposed on the first substrate 300. The first substrate 300 may include a glass substrate, a quartz substrate, a transparent resin substrate, etc. Examples of the transparent resin substrate may include polyimide-based resin, acryl-based resin, polyacrylate-based resin, polyethyleneterephthalate-based resin, polycarbonate-based resin, sulfonic acid-based resin, polyether-based resin, etc.

The buffer layer 305 may prevent the diffusion of metal atoms, metal ions and/or impurities from the first substrate 300. Additionally, the buffer layer 305 may control the heat transfer rate in a successive crystallization process for forming a substantially uniform active pattern 310. Furthermore, the buffer layer 305 may improve the flatness of the first substrate 300 when the first substrate 300 has an irregular surface. The buffer layer 305 may be formed using a silicon compound. For example, the buffer layer 305 may include silicon oxide (SiOx), silicon nitride (SiNx), silicon oxynitride (SiOxNy), silicon oxycarbide (SiOxCy), silicon carbon nitride (SiCxNy), etc. These may be used alone or in a combination thereof. The buffer layer 305 may be obtained by a spin coating process, a chemical vapor deposition (CVD) process, a plasma enhanced chemical vapor deposition (PECVD) process, a high density plasma-chemical vapor deposition (HDP-CVD) process, a printing process, etc. The buffer layer 305 may have a single layer structure or a multi layer structure, which includes at least one silicon compound film. For example, the buffer layer 305 may include a silicon oxide film, a silicon nitride film, a silicon oxynitride film, a silicon oxycarbide film and/or a silicon carbon nitride film.

The active pattern 310 may be disposed on the buffer layer 305. In embodiments, a semiconductor layer (not illustrated) may be formed on the buffer layer 305, and then the semiconductor layer may be patterned to form a preliminary active pattern (not illustrated) on the buffer layer 305. The crystallization process may be performed on the preliminary active pattern to provide the active pattern 310 on the buffer layer 305. The semiconductor layer may be obtained by using a chemical vapor deposition process, a plasma enhanced chemical vapor deposition process, a sputtering process, a low pressure chemical vapor deposition (LPCVD) process, a printing process, etc. When the semiconductor layer includes amorphous silicon, the active pattern 310 may include polysilicon. Further, the crystallization process for forming the active pattern 310 may include a laser irradiation process, a thermal treatment process, a thermal treatment process using a catalyst, etc.

A gate insulation layer 315 may be disposed on the buffer layer 305 to cover the active pattern 310. The gate insulation layer 315 may be formed by a chemical vapor deposition process, a spin coating process, a plasma enhanced chemical vapor deposition process, a sputtering process, a vacuum evaporation process, a high density plasma-chemical vapor deposition process, a printing process, etc. The gate insulation layer 315 may include silicon oxide, metal compound, etc. For example, the gate insulation layer 315 may be formed using the metal compound such as hafnium oxide (HfOx), aluminum oxide (AlOx), zirconium oxide (ZrOx), titanium oxide (TiOx), tantalum oxide (TaOx), etc. These may be used alone or in a combination thereof.

Referring now to FIG. 13, a gate electrode 320 may be disposed on the gate insulation layer 315. The gate electrode 320 may be positioned on a portion of the gate insulation layer 315 under which the active pattern 310 is located. In embodiments, a first conductive layer (not illustrated) may be formed on the gate insulation layer 315, and then the first conductive layer may be patterned by a photolithography process or an etching process using an additional etching mask. Hence, the gate electrode 320 may be formed on the gate insulation layer 315. The first conductive layer may be formed by a printing process, a chemical vapor deposition process, a pulsed laser deposition (PLD) process, a vacuum evaporation process, an atomic layer deposition (ALD) process, etc. The gate electrode 320 may include metal, alloy, metal nitride, conductive metal oxide, a transparent conductive material, etc. For example, the gate electrode 320 may be formed using aluminum (Al), alloy containing aluminum, aluminum nitride (AlNx), silver (Ag), alloy containing silver, tungsten (W), tungsten nitride (WNx), copper (Cu), alloy containing copper, nickel (Ni), chrome (Cr), chrome nitride (CrNx), molybdenum (Mo), alloy containing molybdenum, titanium (Ti), titanium nitride (TiNx), platinum (Pt), tantalum (Ta), tantalum nitride (TaNx), neodymium (Nd), scandium (Sc), strontium ruthenium oxide (SRO), zinc oxide (ZnOx), indium tin oxide (ITO), tin oxide (SnOx), indium oxide (InOx), gallium oxide (GaOx), indium zinc oxide (IZO), etc. These may be used alone or in a combination thereof. Further, the gate electrode 320 may have a single layer structure or a multi layer structure, which may include a metal layer, an alloy layer, a metal nitride layer, a conductive metal oxide layer and/or a transparent conductive material layer.

Although it is not illustrated in FIG. 13, a gate line may be formed on the gate insulation layer 315 while forming the gate electrode 320 on the gate insulation layer 315. The gate electrode 320 may make contact with the gate line, and the gate line may extend on the gate insulation layer 315 along a first direction.

Using the gate electrode 320 as an ion implantation mask, impurities may be doped into portions of the active pattern 310, so that a source region and a drain region may be formed at lateral portions of the active pattern 310. Here, the impurities may not be implanted into a central portion of the active pattern 310 where the gate electrode 320 is positioned, such that the central portion of the active pattern 310 may be defined as a channel region between the source and the drain regions.

An insulation interlayer 325 covering the gate electrode 320 may be disposed on the gate insulation layer 315. The insulation interlayer 325 may be substantially uniformly formed along a profile of the gate electrode 320. The insulation interlayer 325 may include a silicon compound. For example, the insulation interlayer 325 may be formed using silicon oxide, silicon nitride, silicon oxynitride, silicon oxycarbide, silicon carbon nitride, etc. These may be used alone or in a combination thereof. In addition, the insulation interlayer 325 may be formed by a spin coating process, a chemical vapor deposition process, a plasma enhanced chemical vapor deposition process, a high density plasma-chemical vapor deposition process, etc. The insulation interlayer 325 may electrically insulate the gate electrode 320 from a source electrode 330 and a drain electrode 335 successively formed.

As illustrated in FIG. 13, the source and the drain electrodes 330 and 335 may pass through the insulation interlayer 325. The source and the drain electrodes 330 and 335 may be adjacent to the gate electrode 320, and may be spaced apart centering the gate electrode 320. The source and the drain electrodes 330 and 335 may respectively make contact with the source and the drain regions through the insulation interlayer 325.

In embodiments, the insulation interlayer 325 may be partially etched to form holes that expose portions of the source and the drain regions. After a second conductive layer (not illustrated) may be formed on the insulation interlayer 325 to fill the holes, the second conductive layer may be patterned to form the source and the drain regions 330 and 335 as illustrated in FIG. 13. Here, the second conductive layer may be obtained by a sputtering process, a chemical vapor deposition process, a pulsed laser deposition process, a vacuum evaporation process, an atomic layer deposition process, a printing process, etc. Each of the source and the drain electrodes 330 and 335 may include metal, alloy, metal nitride, conductive metal oxide, a transparent conductive material, etc. For example, each of the source and the drain electrodes 330 and 335 may be formed using aluminum, alloy containing aluminum, silver, alloy containing silver, tungsten, tungsten nitride, copper, alloy containing copper, nickel, chrome, chrome nitride, molybdenum, alloy containing molybdenum, titanium, titanium nitride, platinum, tantalum, tantalum nitride, neodymium, scandium, strontium ruthenium oxide, zinc oxide, indium tin oxide, tin oxide, indium oxide, gallium oxide, indium zinc oxide, indium gallium oxide, etc. These may be used alone or in a combination thereof.

Although it is not illustrated in FIG. 13, a data line may be formed on the insulation interlayer 325 while forming the source and the drain electrodes 330 and 335 on the insulation interlayer 325. The data line may extend along a second direction substantially perpendicular to the first direction. The data line may be connected to the source electrode 330.

As the formation of the source and the drain electrodes 330 and 335 on the insulation interlayer 325, the switching device may be provided on the first substrate 300. In this case, the switching device may be a thin film transistor (TFT) that includes the active pattern 310, the gate insulation layer 315, the gate electrode 320, the source electrode 330 and the drain electrode 335.

An insulation layer 340 may be disposed on the insulation interlayer 325 to cover the source and the drain electrodes 330 and 335. The insulation layer 340 may have a relative large thickness that may sufficiently cover the source and the drain electrodes 330 and 335. The insulation layer 340 may include an organic material or an inorganic material. For example, the insulation layer 340 may be formed using photoresist, acryl-based resin, polyimide-based resin, polyamide-based resin, siloxane-based resin, resin containing photo sensitive acryl carboxyl group, novolac resin, alkali-soluble resin, silicon oxide, silicon nitride, silicon oxynitride, silicon oxycarbide, silicon carbon nitride, etc. These may be used alone or in a combination thereof. In accordance with the ingredient in the insulation layer 340, the insulation layer 340 may be obtained by a spin coating process, a sputtering process, a chemical vapor deposition process, an atomic layer deposition process, a plasma enhanced chemical vapor deposition process, a high density plasma-chemical vapor deposition process, a vacuum evaporation process, etc.

By a photolithography process or an etching process using an additional etching mask, a contact hole may be formed through the insulation layer 340 to expose a portion of the drain electrode 335. The first electrode 345 may be disposed on the insulation layer 340 to fill the contact hole. Thus, the drain electrode 345 may contact with the drain electrode 335. In some embodiments, a contact, a plug or a pad may be provided on the drain electrode 335 to fill the contact hole. Here, the first electrode 345 may be electrically connected to the drain electrode 335 through the contact, the plug or the pad.

The first electrode 345 may include metal having a reflectivity, alloy having a reflectivity, etc. For example, the first electrode 345 may be formed using aluminum, silver, platinum, gold (Au), chrome, tungsten, molybdenum, titanium, palladium (Pd), iridium (Ir), alloys thereof, etc. These may be used alone or in a combination thereof. Further, the first electrode 345 may be formed by a printing process, a sputtering process, a chemical vapor deposition process, an atomic layer deposition process, a pulsed laser deposition process, etc.

A pixel defining layer 350 may be disposed on the first electrode 345 and the insulation layer 340. The pixel 350 may include an organic material or an inorganic material. For example, the pixel defining layer 350 may be formed using photoresist, polyacryl-based resin, polyimide-based resin, acryl-based resin, a silicon compound, etc. Additionally, the pixel defining layer 350 may be formed on the first electrode 345 by a spin coating process, a spray process, a printing process, a chemical vapor deposition process, etc.

The pixel defining layer 350 may be partially etched to form an opening that exposes a portion of the first electrode 345. The opening of the pixel defining layer 350 may define a luminescent region and a non-luminescent region of the display device. That is, a region having the opening of the pixel defining layer 350 may be the luminescent region of the display device.

The light emitting structure 355 may be disposed on the exposed first electrode 345 and a portion of the pixel defining layer 350. The light emitting structure 355 may have a multi layer structure that includes an organic light emitting layer (EL), a hole injection layer (HIL), a hole transfer layer (HTL), an electron transfer layer (ETL), an electron injection layer (ETL), etc. The organic light emitting layer of the light emitting structure 355 may include a material generating a red color of light, a material generating a green color of light or a material generating a blue color of light in accordance with pixels of the display device. In some embodiments, the organic light emitting layer may have a multi layer stacked structure including material films for emitting a red color of light, a green color of light and a blue color of light to thereby generate a white color of light.

The second electrode 360 may be disposed on the light emitting structure 355 and the pixel defining layer 350. The second electrode 360 may include a transparent conductive material such as indium tin oxide, indium zinc oxide, tin oxide, zinc oxide, indium gallium oxide, gallium oxide, etc. These may be used alone or in a combination thereof. Further, the second electrode 360 may be obtained by a sputtering process, a chemical vapor deposition process, an atomic layer deposition process, a pulsed laser deposition process, a printing process, etc.

The second substrate 365 may be disposed on the second electrode 360. The second substrate 365 may include a transparent insulation substrate. For example, the second substrate 365 may include a glass substrate, a quartz substrate, a transparent resin substrate, etc.

The polarization structure 370 may be disposed on the second substrate 365. In this case, the polarization structure 370 may be any one of the polarization structure illustrated in FIG. 3, the polarization structure illustrated in FIG. 6, the polarization structure illustrated in FIG. 8, the polarization structure illustrated in FIG. 10 or the polarization structure illustrated in FIG. 12. When the display device includes the polarization structure 370, the display device may include a bezel having a minimized size or may not include a bezel. Further, the uniformity of the image displayed by the display device may be improved at all the regions of the display panel of the display device.

According to embodiments, when a polarization structure having a light blocking member is employed in a display device, the display device may include a bezel having a considerably reduced size, or the display device may not require any bezel on a display panel. Thus, the display device may ensure beautiful appearance and also the display device may display an image with enhanced uniformity and visibility in the whole display area. Such a display device may be used as various display apparatuses, for example, a television, a monitor, a note book computer, a cellular phone, a portable display device, a portable media player, etc.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the invention. Accordingly, all such modifications are intended to be included within the scope of the invention as defined in the claims. In the claims, means-plus-function clauses are intended to cover the structures described herein as performing the recited function and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A polarization structure comprising:
a first adhesion layer;
a phase retarder layer disposed over the first adhesion layer;
a polarization layer disposed over the phase retarder layer; and
a light blocking member disposed over a peripheral portion of the polarization layer.

2. The polarization structure of claim 1, wherein the light blocking member has a frame shape or a ring shape.

3. The polarization structure of claim 1, wherein the light blocking member comprises one selected from the group consisting of metal, alloy, metal compound, black material, insulation resin and light blocking paint.

4. The polarization structure of claim 1, wherein the light blocking member comprises one selected from the group consisting of cobalt carbide (CoCx), iron oxide (FeOx), terbium (Tb)-based compound, diamond-like carbon, titanium black, chrome (Cr), molybdenum (Mo), chrome oxide (CrOx), molybdenum oxide (MoOx), phenylene black, aniline black, cyanine black, nigrosine acid black, black resin, ink containing polyethyleneterephthalate (PET)-based resin and ink containing urethane resin.

5. The polarization structure of claim 1, further comprising a protection layer disposed over the polarization layer wherein the light blocking member is disposed on a peripheral portion of the protection layer.

6. The polarization structure of claim 5, further comprising a low reflective layer disposed over the protection layer and the light blocking member.

7. The polarization structure of claim 1, further comprising a second adhesion layer disposed over the polarization layer, wherein the light blocking member is disposed on a peripheral portion of the second adhesion layer.

8. The polarization structure of claim 7, further comprising:
a protection layer disposed over the light blocking member and the second adhesion layer; and
a low reflective layer disposed over the protection layer.

9. The polarization structure of claim 7, further comprising:
a first protection layer disposed over the phase retarder layer and the polarization layer;
a second protection layer disposed over the light blocking member and the second adhesion layer; and
a low reflective layer disposed over the second adhesion layer.

10. A polarization structure comprising:
an adhesion layer;
a light blocking member disposed over a peripheral portion of the adhesion layer;
a phase retarder layer disposed over the light blocking member and the adhesion layer;
a polarization layer disposed over the phase retarder layer;
a protection layer disposed over the polarization layer; and
a low reflective layer disposed over the protection layer.

11. A polarization structure comprising:
a first adhesion layer;
a phase retarder layer disposed over the first adhesion layer;
a second adhesion layer disposed over the phase retarder layer;
a light blocking member disposed over a peripheral portion of the second adhesion layer;
a polarization layer disposed over the light blocking member and the second adhesion layer;
a protection layer disposed over the polarization layer; and
a low reflective layer disposed over the protection layer.

12. A method of manufacturing a polarization structure, comprising:
providing a base film;
forming a first adhesion layer over the base film;
forming a phase retarder layer over the first adhesion layer;
forming a polarization layer over the phase retarder layer;
forming a light blocking member over a peripheral portion of the polarization layer; and
forming a low reflective layer over the light blocking member and the polarization layer.

13. The method of claim 12, wherein forming the light blocking member comprises:
forming a light blocking layer over the polarization layer;
forming a mask over the light blocking layer; and
patterning the light blocking layer using the mask.

14. The method of claim 12, wherein forming the light blocking member comprises:
forming a preliminary light blocking member over the peripheral portion of the polarization layer; and
thermally treating the preliminary light blocking member.

15. The method of claim 12, wherein the light blocking member is formed with an adhesive comprising black dye.

16. The method of claim 12, further comprising forming a protection layer over the polarization, layer wherein the light blocking member is disposed on a peripheral portion of the protection layer.

17. The method of claim 12, further comprising forming a second adhesion layer over the polarization layer, wherein the light blocking member is disposed on a peripheral portion of the second adhesion layer.

18. The method of claim 17, further comprising forming a protection layer over the light blocking member and the second adhesion layer.

19. The method of claim 17, further comprising:
forming a first protection layer between the phase retarder layer and the polarization layer; and
forming a second protection layer between the light blocking member and the second adhesion layer.

20. A method of manufacturing a polarization structure, comprising:
providing a base film;
forming an adhesion layer over the base film;
forming a light blocking member over a peripheral portion of the adhesion layer;
forming a phase retarder layer over the light blocking member and the adhesion layer;
forming a polarization layer over the phase retarder layer;
forming a protection layer over the polarization layer; and
forming a low reflective layer over the protection layer.

21. A method of manufacturing a polarization structure, comprising:
providing a base film;
forming a first adhesion layer over the base film;
forming a phase retarder layer over the first adhesion layer;
forming a second adhesion layer over the phase retarder layer;
forming a light blocking member over a peripheral portion of, the second adhesion layer;
forming a polarization layer over the light blocking member and the second adhesion layer;
forming a protection layer over the polarization layer; and
forming a low reflective layer over the protection layer.

22. A display device including a polarization structure, comprising:
a first substrate comprising a switching device;
a first electrode electrically connected to the switching device;
a pixel defining layer disposed over the first electrode, the pixel defining layer having an opening exposing the first electrode;
a light emitting structure disposed over the exposed portion of the first electrode;
a second electrode disposed over the light emitting structure;
a second substrate disposed over the second electrode; and
a polarization structure disposed over the second substrate, the polarization structure comprising a light blocking member disposed at a peripheral portion.
